(19) United States
(12) Patent Application Publication
(10) Pub. No.: US 2014/0290843 A1
(43) Pub. Date: Oct. 2, 2014

(54) METHOD OF PREPARING AN ADHESIVE FILM INTO A PRECUT SEMICONDUCTOR WAFER SHAPE ON A DICING TAPE

(71) Applicant: HENKEL IP & HOLDING GMBH, Duesseldorf (DE)

(72) Inventors: YounSang Kim, Foothill Ranch, CA (US); Jeffrey Grey, Orange, CA (US); Kevin Becker, Cerritos, CA (US)

(21) Appl. No.: 14/303,008

(22) Filed: Jun. 12, 2014

Related U.S. Application Data
(63) Continuation of application No. PCT/US2012/065982, filed on Nov. 20, 2012.
(60) Provisional application No. 61/576,100, filed on Dec. 15, 2011.

(51) Int. Cl. H01L 21/673

(52) U.S. Cl. CPC H01L 21/673
USPC 156/249

(57) ABSTRACT

A method for removing the trimmed scrap of conductive die attach adhesive film from a carrier support tape is provided. An adhesive film is disposed between a support carrier and a release liner; the release liner and adhesive film are cut into a shape conforming to the shape of a semiconductor wafer. After scrap release liner is removed, a temporary adhesive sheet is mounted over and adhered to the exposed conductive die attach film surrounding the cut shape, and mounted over and adhered to the scrap release liner on the cut shape; the temporary adhesive sheet is removed, and due to its adhesion properties to the adhesive film and release liner, the scrap adhesive film and scrap release liner are removed along with the temporary adhesive sheet.

### BACKGROUND OF THE INVENTION

This invention relates to a method for removing the trimmed scrap of adhesive film from a carrier support tape, in the fabrication process of preparing die attach adhesive on a dicing tape.

Integrated circuits are fabricated on the surfaces of semiconductor wafers, composed of materials such as silicon and gallium-arsenide. The wafer is then separated into individual integrated circuits by dicing the wafer with a saw or laser. Dicing the wafer with a saw or laser stresses the wafer. To counteract the stress, the wafer is supported on a sheet or tape called a dicing tape during the dicing operation. After dicing, the individual integrated circuits are singulated from the wafer, and then bonded to a substrate that is used in the manufacture of the circuits for the ultimate electronic device.

Bonding of the integrated circuit to its substrate is accomplished with an adhesive, known as a die attach adhesive, which comprises an adhesive resin and up to about 90% by weight of conductive filler. The die attach adhesive can be applied to the side of the die opposite the side containing the circuitry or directly to the substrate. Current fabrication operations favor applying the die attach adhesive directly to the back side of the wafer before dicing, as it is more efficient than applying the die attach adhesive to each singulated integrated circuit or a bond site on the substrate.

The die attach adhesive for wafer application is provided as a film in the shape of the semiconductor wafer on a support carrier. To obtain that shape, the support carrier is coated with the adhesive to form a film of adhesive on the support carrier, the figure of the semiconductor is incised into the adhesive film, and the scrap adhesive is trimmed away and removed from the support carrier. To help meet miniaturization requirements the adhesive film is thin, and it is highly loaded with conductive filler, which makes it brittle. As the trimmed scrap is peeled away mechanically, the tension on the adhesive film causes it to break so that some of the trimmed scrap adhesive is not removed from the support carrier. This scrap adhesive film must then be removed manually, causing an interruption in the fabrication process and loss of manufacturing time. This creates a need for a means to completely remove the scrap adhesive film from the support carrier in one operation, leaving only the adhesive film in the figure of the semiconductor wafer for later lamination to the wafer.

### SUMMARY OF THE INVENTION

This invention is directed to a method to remove the trimmed scrap adhesive film from the support carrier. The method comprises (a) providing an assembly of a support carrier, an adhesive film, and a release liner, in that order, in which a figure is incised into the assembly from the direction of the release liner, through the release liner, through the adhesive film, and partially into the support carrier; (b) removing the release liner from the adhesive film that surrounds the incised figure, so that the adhesive film surrounding the incised figure is exposed; (c) adhering a temporary adhesive sheet onto the exposed adhesive film surrounding the incised figure and onto the release liner of the incised figure, in which the temporary adhesive sheet has a higher adhesion to the adhesive film than the adhesive film has to the support carrier, and in which the temporary adhesive has a higher adhesion to the release liner than the release liner has to the adhesive film; and (d) removing the temporary adhesive sheet, which has adhered to the exposed adhesive film and to the remaining release liner, whereby the adhesive film is removed from the support carrier and the release liner is removed from the incised figure of the adhesive film, leaving the incised figure of the adhesive film on the support carrier.

### BRIEF DESCRIPTION OF THE DRAWINGS

FIG. 1 is a depiction of a process for preparing an adhesive film for mounting on a semiconductor wafer.

### DETAILED DESCRIPTION OF THE INVENTION

To prepare a die attach adhesive for application to a semiconductor wafer, the die attach adhesive is first coated onto a carrier support tape or sheet (hereinafter “carrier support”) and heated to remove solvent, if present, or to partially cure the adhesive. This is referred to as B-staging, and brings the adhesive into a film format (herein “adhesive film”) and to a less-tacky state than before the heating.

Suitable die attach adhesives are well known in the art and in many cases are composed of epoxy resins, bismaleimide resins, acrylate resins, or combinations of these. The actual choice of die attach adhesive is not critical to this invention.

A protective tape or sheet (herein “release liner”) is then laminated to the adhesive film with pressure and/or heat; the release liner protects the adhesive film temporarily until the adhesive film is ready for further fabrication steps. The release liner is chosen for the property of being able to release easily and cleanly from the adhesive film.

The support carrier and the release liner can be composed of the same or different materials. One suitable material is product number 8322 from St. Gobain Performance Plastics, which can be used for both the support carrier and the release liner. In general, the B-staging operation causes the adhesive film to adhere more strongly to the carrier support than to the release liner. This differential in release may also be accomplished by choosing a release liner and a carrier support that have a difference in release properties, such that the release liner removes more easily from the adhesive film than the adhesive film removes from the support carrier.

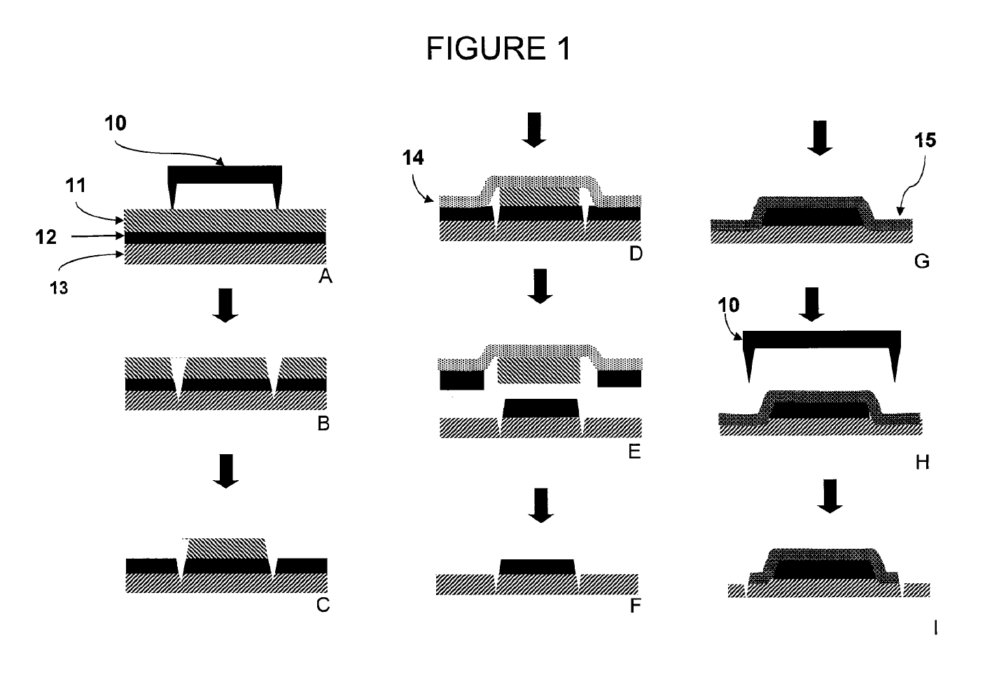

The invention will now be described in reference to FIG. 1, diagrams A through F. Diagrams G, H, and I, are subsequent and separate processing steps in the overall preparation of a conductive die attach adhesive film for application to a semiconductor wafer. The elements 10 through 15 are the same throughout all the diagrams, and are omitted in subsequent diagrams after introduction to keep the Figure uncluttered.

To provide the adhesive film in a format for affixing to the semiconductor wafer, the figure of the semiconductor wafer is incised into the assembly of release liner, adhesive film, and support carrier. The figure typically is a circular shape and typically is slightly larger than the size of the semiconductor wafer. For example, when the wafer diameter is 200 mm, the diameter of the incised shape is usually 220 mm. This amount can be varied by the manufacturer as needed. Hereinafter, “incised figure” shall mean the release liner or adhesive film or both, cut out in the shape of the semiconductor wafer or slightly larger; “scrap release liner”, “scrap adhesive film”, and “scrap dicing tape” shall mean the portion of those materials (release liner, adhesive film, dicing tape) not part of the “incised figure” that are trimmed away after the incision operation.

The incision is performed from the direction of the release liner, through the release liner, the adhesive film, and slightly into the support carrier. The slight cut into the support carrier makes it easier to remove the incised figure of adhesive film from the support carrier to the semiconductor wafer in a later operation. Referring to FIG. 1, diagram A shows the incision tool 10, release liner 11, adhesive film 12, and support carrier 13; diagram B shows the incision.

The scrap release liner surrounding the incised figure is then removed so that the adhesive film surrounding the incised figure is exposed, but the incised figure of the release liner on the adhesive film is left in place. This is depicted in diagram C of FIG. 1.

Referring now to FIG. 1, diagram D, a temporary adhesive sheet 14 is mounted onto the exposed adhesive film surrounding the incised figure of release liner and adhesive film, and onto the incised figure of release liner left in place on the incised figure of the adhesive film. The temporary adhesive sheet is chosen so that it has a higher adhesion to the adhesive film than the adhesive film has to the support carrier, and so that it has a higher adhesion to the release liner than the release liner has to the adhesive film. The temporary adhesive sheet then is removed, shown in diagram E. Due to its adhesion properties, the temporary adhesive sheet adheres to and removes the scrap adhesive film from the support carrier, and adheres to and removes as scrap the incised release liner adhering to the incised figure of adhesive film. This step leaves an incised figure of adhesive film on the support carrier, as shown in diagram F.

Commercially available temporary adhesive sheets or tapes are available; one suitable sheet is a silicone coated 2 mil PET sheet with a water-based acrylic pressure sensitive adhesive from Sekisui TA IndustriesTape.

In subsequent fabrication steps, a dicing tape 15 is disposed over the adhesive film and support carrier surface surrounding the incised figure of the adhesive film as shown in diagram G. Commercially available dicing tapes are product numbers ERX-6140 and ERX-0045 from Denka. An incision tool 10 is used to cut through the dicing tape and support carrier surrounding the incised figure of the adhesive film, shown in diagram H. The scrap dicing tape is removed, leaving the adhesive film in the figure of the semiconductor wafer on the support carrier and protected with the dicing tape, depicted in diagram I.

1. A method for removing the trimmed scrap of adhesive film from a carrier support tape, the method comprising:
(a) providing an assembly of a support carrier, an adhesive film, and a release liner, in that order, in which a figure is incised into the assembly from the direction of the release liner, through the release liner, through the adhesive film, and partially into the support carrier;
(b) removing the release liner from the adhesive film that surrounds the incised figure, so that the adhesive film surrounding the incised figure is exposed;
(c) adhering a temporary adhesive sheet onto the exposed adhesive film surrounding the incised figure and onto the release liner of the incised figure, in which the temporary adhesive sheet has a higher adhesion to the adhesive film than the adhesive film has to the support carrier, and in which the temporary adhesive has a higher adhesion to the release liner than the release liner has to the adhesive film; and
(d) removing the temporary adhesive sheet, which has adhered to the exposed adhesive film and to the remaining release lint, whereby the adhesive film is removed from the support carrier and the release liner is removed from the incised figure of the adhesive film, leaving the incised figure of the adhesive film on the support carrier.
